(19) United States
(12) Patent Application Publication
(10) Pub. No.: US 2024/0339338 A1
(43) Pub. Date: Oct. 10, 2024

(54) WAFER PROCESSING APPARATUS FOR COMBINED HIGH-PRESSURE PROCESS AND VACUUM PROCESS, AND WAFER PROCESSING METHOD USING DECOMPRESSION

(71) Applicant: HPSP Co., Ltd., Hwaseong-si (KR)

(72) Inventor: Chul Hee SHIN, Yongin-si (KR)

(73) Assignee: HPSP Co., Ltd., Hwaseong-si (KR)

(21) Appl. No.: 18/750,482

(22) Filed: Jun. 21, 2024

Related U.S. Application Data
(63) Continuation of application No. PCT/KR2022/020876, filed on Dec. 20, 2022.

(30) Foreign Application Priority Data
Dec. 23, 2021 (KR) 10-2021-0185714

(51) Int. Cl. H01L 21/67

(52) U.S. Cl. CPC H01L 21/67017

(57) ABSTRACT

The present invention provides a wafer processing apparatus for a combined high-pressure process and vacuum process, and a wafer processing method using decompression, the wafer treatment apparatus comprising: a process chamber having a processing area for processing a wafer; a gas supply module configured to supply a processing gas to the processing area for the processing area to reach a high-pressure state; gas exhaust module configured to exhaust the processing gas from the processing area for the processing area to reach a normal-pressure state; a gas intake module configured to suction residual gas in the processing gas from the processing area for the processing area to reach a vacuum state; and a control module configured to control the gas supply module, the gas exhaust module, and the gas intake module for the wafer processing to be performed under pressure changes from the high-pressure state through the normal-pressure state to the vacuum state.

### TECHNICAL FIELD

The present invention relates to a wafer processing apparatus for a combined high-pressure process and vacuum process, and a wafer processing method using decompression.

### BACKGROUND ART

An entire process of manufacturing a semiconductor may include a number of consecutive processes. Most of the processes may be performed under an appropriate vacuum state to maintain a clean condition. On the other hand, a high vacuum process may be performed to deposit a metal material on a wafer. There may also be a high-pressure process for heat treating the wafer under a high-pressure gas atmosphere.

The high vacuum process and the high-pressure process may require greatly different pressure conditions. For example, the high vacuum process may proceed at a pressure much lower than atmospheric pressure, and the high-pressure process may proceed at a pressure much higher than the atmospheric pressure. To satisfy these completely different conditions, these processes may be performed in separate equipment (chambers).

For the development of a new technology or an improvement to the existing processes, the high-pressure process may be added to the (high) vacuum process, or vice versa. In addition, pressure conditions may need to be adjusted by switching between a high pressure and vacuum in a single processing. In this case, a pressure change may be required over a wide range from the high pressure to the vacuum. However, a technology for appropriately responding to this change has not yet been developed.

### DISCLOSURE

### Technical Problem

An object of the present invention is to provide a wafer processing apparatus for a combined high-pressure process and vacuum process that may convert a pressure from a high pressure to vacuum in a single chamber, thus allowing a wafer to be processed under a large pressure change, and a wafer processing method using decompression.

### Technical Solution

According to an embodiment of the present invention, provided is a wafer processing method using decompression, the method including: supplying a processing gas to a processing area for the processing area to be in a high-pressure state that is higher than that of atmospheric pressure, thereby exposing a wafer disposed in the processing area to the high-pressure state; exhausting the processing gas from the processing area for the processing area to be converted to a normal-pressure state, thereby exposing the wafer to decompression from a high pressure to a normal pressure; and suctioning residual gas in the processing gas from the processing area for the processing area to be converted to the vacuum state, thereby exposing the wafer to decompression from the normal pressure to vacuum.

In the high-pressure state, a pressure in the processing area may reach a set value within a range of 2 ATM to 25 ATM.

In the vacuum state, a pressure in the processing area may reach a set value within a range of 10\hat{ }−3 Torr to 10\hat{ }−7 Torr.

When a pressure is converted from the high-pressure state to the vacuum state, a decompression magnitude may be 2 ATM or more.

The method may further include maintaining a pressure in a protective area accommodating the processing area to be higher than a pressure in the processing area while converting the processing area to the vacuum state from the high-pressure state.

In the suctioning of the residual gas in the processing gas from the processing area for the processing area to be converted to the vacuum state, thereby exposing the wafer to the decompression from the normal pressure to vacuum, a pressure in a protective area accommodating the processing area may be maintained to be in the normal-pressure state or more when converting the processing area to the vacuum state.

In the exhausting of the processing gas from the processing area for the processing area to be converted to the normal-pressure state, thereby exposing the wafer to the decompression from the high pressure to the normal pressure, a gas exhaust valve for regulating a gas exhaust pipe connected to the processing area may be opened to naturally exhaust the processing gas.

The suctioning of the residual gas in the processing gas from the processing area for the processing area to be converted to the vacuum state, thereby exposing the wafer to the decompression from the normal pressure to vacuum, may include operating a first vacuum pump communicating to the processing area, and operating a second vacuum pump disposed between the processing area and the first vacuum pump, and operated at a lower pressure than the first vacuum pump, wherein the first vacuum pump is operated by being bypass-connected to a flow path between the processing area and the second vacuum pump when the second vacuum pump is not operated.

The method may further include bringing a temperature of the processing area to a set value within a range of 300° C. to 800° C. while converting the processing area to the vacuum state from the high-pressure state.

According to another embodiment of the present invention, provided is a wafer processing apparatus for a combined high-pressure process and vacuum process, the apparatus including: a process chamber having a processing area for processing a wafer; a gas supply module configured to supply a processing gas to the processing area for the processing area to reach a high-pressure state that is higher than that of atmospheric pressure; a gas exhaust module configured to exhaust the processing gas from the processing area for the processing area to reach a normal-pressure state; a gas intake module configured to suction residual gas in the processing gas from the processing area for the processing area to reach a vacuum state; and a control module configured to control the gas supply module, the gas exhaust module, and the gas intake module for the wafer processing to be performed under pressure changes from the high-pressure state through the normal-pressure state to the vacuum state.

The process chamber may include an internal chamber including the processing area, and an external chamber accommodating the internal chamber, and the gas supply module may be configured to supply, to the external chamber, a protective gas at a pressure higher than a pressure of the processing gas.

The gas intake module may include a suction unit, and a suction pipe allowing the suction unit and the processing area to communicate with each other, and the gas exhaust module includes a gas exhaust pipe branching off from the suction pipe and having a smaller diameter than the suction pipe.

According to still another embodiment of the present invention, provided is a wafer processing method using decompression, the method including: decompressing a processing area from a high-pressure state to at least one of the high-pressure state, a normal-pressure state, and a vacuum state among the high-pressure state where a processing gas is supplied to the processing area for the processing area to have a pressure higher than atmospheric pressure, the normal-pressure state where the processing gas is exhausted from the processing area and the processing area reaches a normal pressure, and the vacuum state where residual gas in the processing gas is suctioned from the processing area and the processing area reaches vacuum; and causing outgassing in a wafer disposed in the processing area by decompressing the processing area, wherein in the decompressing of the processing area from the high-pressure state to the at least one of the high-pressure state, the normal-pressure state, and the vacuum state among the high-pressure state where the processing gas is supplied to the processing area for the processing area to have the pressure higher than the atmospheric pressure, the normal-pressure state where the processing gas is exhausted from the processing area and the processing area reaches the normal pressure, and the vacuum state where the residual gas in the processing gas is suctioned from the processing area and the processing area reaches the vacuum, a decompression magnitude may be 2 ATM or more.

The method may further include bringing a temperature of the processing area to a set value within a range of 300° C. to 800° C. when pressing and decompressing the wafer.

In the bringing of the temperature of the processing area to the set value within the range of 300° C. to 800° C. when pressing and decompressing the wafer, a temperature of the processing area may be maintained at the same temperature while decompressing the wafer.

### Advantageous Effects

According to the wafer processing apparatus for a combined high-pressure process and vacuum process, and the wafer processing method using decompression according to the present invention configured as above, the wafer disposed in the processing area may be exposed to the decompression from the high pressure through the normal pressure to the vacuum to thus be influenced by the large pressure change. The wafer may undergo the pressure changes in the single chamber (or the processing area), and the new wafer-processing method may thus be achieved using these changes.

### DESCRIPTION OF DRAWINGS

FIG. 1 is a conceptual diagram of a wafer processing apparatus 100 for a combined high-pressure process and vacuum process according to an embodiment of the present invention.

FIG. 2 is a conceptual diagram for explaining an operation state of a gas intake module 150 in FIG. 1.

FIG. 3 is a conceptual diagram for explaining a different operation state of the gas intake module 150 in FIG. 1.

FIG. 4 is a block diagram showing a control configuration of the wafer processing apparatus 100 for a combined high-pressure process and vacuum process in FIG. 1.

FIG. 5 is a flowchart for explaining a wafer processing method using decompression according to another embodiment of the present invention.

FIG. 6 is a flowchart for explaining a wafer processing method using decompression according to still another embodiment of the present invention.

FIG. 7 is a flowchart for explaining a wafer processing method using decompression according to yet another embodiment of the present invention.

### BEST MODEL

Hereinafter, a wafer processing apparatus for combined high-pressure process and vacuum process, and a wafer processing method using decompression according to embodiments of the present invention are described in detail with reference to the accompanying drawings. Throughout the present invention, components that are the same as or similar to each other are denoted by reference numerals that are the same as or similar to each other even in a different embodiment, and a description thereof is replaced by the first description.

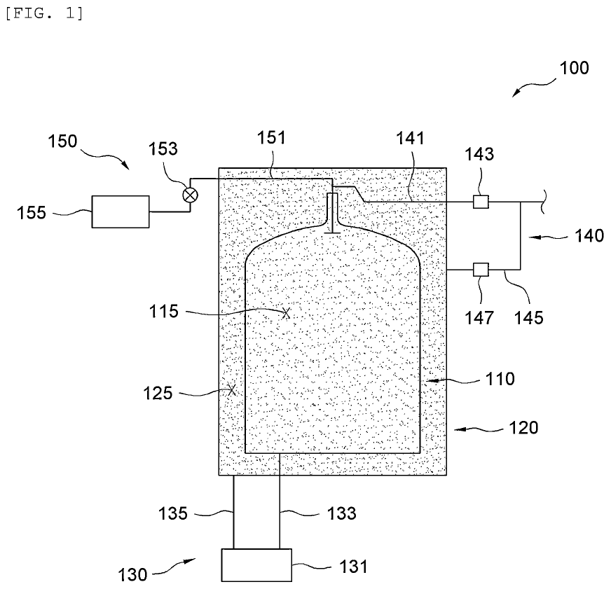

FIG. 1 is a conceptual diagram of a wafer processing apparatus 100 for a combined high-pressure process and vacuum process according to an embodiment of the present invention.

Referring to this drawing, the wafer processing apparatus 100 for a combined high-pressure process and vacuum process may include an internal chamber 110, an external chamber 120, a gas supply module 130, a gas exhaust module 140, and a gas intake module 150.

The internal chamber 110 may have a processing area 115 for processing an object, for example, a semiconductor wafer. The internal chamber 110 may be made of a non-metallic material, for example, quartz, to reduce a possibility that contaminants (particles) occur in a processing environment. Although simplified in the drawing, a door (not shown) for opening the processing area 115 may be disposed at a lower end of the internal chamber 110. As the door descends, the processing area 115 may be opened, and the wafer may be input into the processing area 115 while being mounted on a holder (not shown). The holder may be a wafer boat capable of stacking the wafers in a plurality of layers.

The external chamber 120 may accommodate the internal chamber 110. Unlike the internal chamber 110, the external chamber 120 is free from a problem of contamination of the wafer, and may thus be made of a metal material. The external chamber 120 may have a protective area 125 accommodating the internal chamber 110. The external chamber 120 may also have a door (not shown) disposed in its lower portion. The door may descend together with the door of the internal chamber 110, and open the protective area 125. The external chamber 120 and the internal chamber 110 may be collectively referred to as a process chamber.

The gas supply module 130 may be configured to supply a gas to the chamber 110 or 120. The gas supply module 130 may have a gas supplier 131 communicating with a utility (or gas supply facility) of a semiconductor factory. The gas supplier 131 may provide the internal chamber 110, specifically the processing area 115, with a processing gas such as hydrogen, deuterium, nitrogen, or argon gas. The processing gas may be supplied as an active gas and/or an inert gas based on a feature of the wafer processing. The gas supplier 131 may provide the protective area 125 with, a protective gas such as the nitrogen or argon gas, which is the inert gas. The protective gas injected in the protective area 125 may specifically fill a region of the protective area 125 that excludes the internal chamber 110. The gas may be injected into the processing area 115 or the protective area 125 through a processing gas line 133 or a protective gas line 135.

The processing gas or the protective gas may be supplied to form a high-pressure state that is higher than that of atmospheric pressure, in which, for example, a pressure ranges from several ATM to tens of ATM. For example, in the high-pressure state, a pressure in the processing area 115 may reach a set value within a range of 2 ATM to 25 ATM. In addition, when a pressure of the processing gas is a first pressure, and a pressure of the protective gas is a second pressure, these pressures may maintain a predetermined relationship. For example, the second pressure may be set to be slightly higher than the first pressure. Such a pressure difference may prevent the processing area 115 from being damaged, and also prevent the processing gas from leaking from the processing area 115.

The gas exhaust module 140 may be configured to exhaust the processing gas or the protective gas from the chamber 110 or 120. To exhaust the processing gas from the internal chamber 110, specifically the processing area 115, a gas exhaust pipe 141 may be connected to the top of the internal chamber 110. In detail, the exhausted processing gas may be mixed with an impurity gas or the like produced during the wafer processing. A gas discharger 143 may be installed at the gas exhaust pipe 141. The gas discharger 143 may be a valve for regulating the exhaust of the processing gas.

A gas exhaust pipe 145 communicating with the external chamber 120 and a gas discharger 147 installed thereat may be provided to also discharge the protective gas from the external chamber 120, specifically from the protective area 125. These gas exhaust pipes 141 and 145 may communicate with each other. Accordingly, the processing gas may be exhausted while being diluted in the protective gas.

When a gas exhaust valve 143 or 147 is opened, the processing gas or the protective gas may be naturally exhausted due to its high pressure. Accordingly, the processing area 115 or the protective area 125 may be decompressed from the high pressure, which is higher than the atmospheric pressure, to a normal pressure.

The gas intake module 150 may be configured to suction residual gas in the processing gas from the processing area 115. The gas intake module 150 may be operated at a normal-pressure state, thus bringing the processing area 115 to a vacuum state. In the vacuum state, a pressure in the processing area 115 may reach a set value within a range of 10\hat{ }−3 Torr to 10\hat{ }−7 Torr.

In detail, the gas intake module 150 may include a suction pipe 151, a shutoff valve 153, and a suction unit 155. The suction pipe 151 may allow the processing area 115 and the suction unit 155 to communicate with each other. The suction pipe 151 may communicate with the top of the processing area 115. The gas exhaust pipe 141 described above may branch off from the suction pipe 151 and have a smaller diameter than the suction pipe 151. The shutoff valve 153 may regulate the suction pipe 151. The shutoff valve 153 may be closed when the gas exhaust module 140 is operated, and the shutoff valve 153 may be opened when the suction unit 155 is operated. The suction unit 155 may suction the residual gas in the processing area 115 through the suction pipe 151, and externally withdraw the same from the processing area 115.

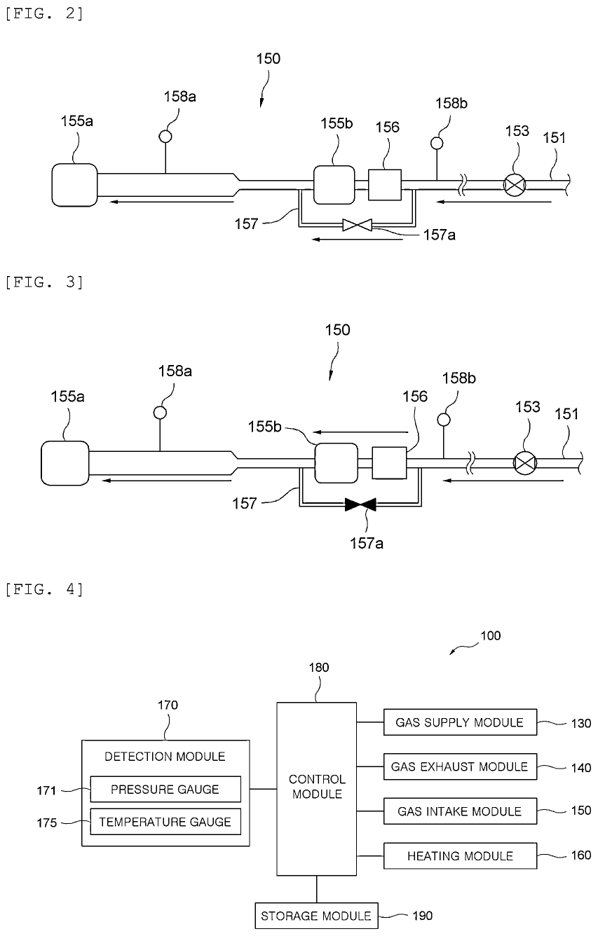

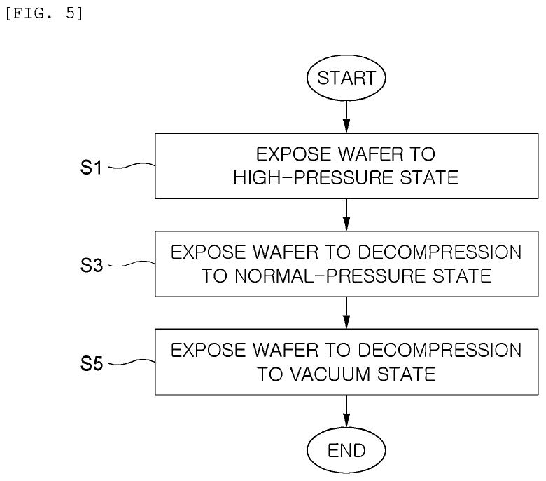

A detailed configuration of the gas intake module 150 is further described with reference to FIGS. 2 and 3. FIG. 2 is a conceptual diagram for explaining an operation state of the gas intake module 150 in FIG. 1, and FIG. 3 is a conceptual diagram for explaining a different operation state of the gas intake module 150 in FIG. 1.

With further reference to these drawings, the suction unit 155 may include a first vacuum pump 155a and a second vacuum pump 155b. The second vacuum pump 155b may be operated at a lower pressure than the first vacuum pump 155a. For example, if the first vacuum pump 155a is a dry pump, the second vacuum pump 155b may be a turbo molecular pump.

The first vacuum pump 155a may communicate with the processing area 115 through the suction pipe 151. The second vacuum pump 155b may be disposed between the first vacuum pump 155a and the processing area 115. An automatic pressure adjuster 156 may be installed upstream of the second vacuum pump 155b. In order to bypass the second vacuum pump 155b, a bypass pipe 157 may be connected to the suction pipe 151. A bypass valve 157a may be installed at the bypass pipe 157. A pressure gauge 158a or 158b may be installed upstream of the first vacuum pump 155a or upstream of the second vacuum pump 155b to detect a pressure at a corresponding point of the suction pipe 151.

Through this configuration, the second vacuum pump 155b may not be operated when the first vacuum pump 155a is operated. The first vacuum pump 155a may suction the residual gas through the bypass pipe 157 in a state where the bypass valve 157a is opened (see FIG. 2).

The first vacuum pump 155a may also be operated when the second vacuum pump 155b is operated. The bypass valve 157a may be closed (see FIG. 3) when the second vacuum pump 155b is operated. The residual gas suctioned through the second vacuum pump 155b may be finally discharged through the first vacuum pump 155a.

The description describes a control configuration of the wafer processing apparatus 100 for a combined high-pressure process and vacuum process with reference to FIG. 4. FIG. 4 is a block diagram showing the control configuration of the wafer processing apparatus 100 for a combined high-pressure process and vacuum process in FIG. 1.

Referring to this drawing (and FIGS. 1 to 3), the wafer processing apparatus 100 for a combined high-pressure process and vacuum process may further include a heating module 160, a detection module 170, a control module 180, and a storage module 190 in addition to the gas supply module 130 or the like, described above.

The heating module 160 may be configured to increase a temperature of the processing area 115. The temperature of the processing area 115 (and that of the processing gas) may reach hundreds of degrees Celsius based on an operation of the heating module 160. The heating module 160 may include a heater (not shown) disposed in the protective area 125.

The detection module 170 may be configured to detect an environment of the chamber 110 or 120. The detection module 170 may include a pressure gauge 171 and a temperature gauge 175. The pressure gauge 171 and the temperature gauge 175 may be installed in each of the chambers 110 and 120.

The control module 180 may be configured to control the gas supply module 130, the gas exhaust module 140, or the like. The control module 180 may control the gas supply module 130 or the like based on a detection result of the detection module 170.

The storage module 190 may be configured to store data, programs, or the like that the control module 180 may refer to for the control. The storage module 190 may include at least one type of storage medium among a flash memory, a hard disk, a magnetic disk, and an optical disk.

Through this configuration, the control module 180 may control the gas supply module 130 or the like to perform the wafer processing according to an embodiment of the present invention.

In detail, the control module 180 may control an operation of the gas supply module 130 based on a pressure in the chamber 110 or 120 that is acquired through the pressure gauge 171. Based on the operation of the gas supply module 130, the chambers 110 and 120 may respectively be filled with the processing gas at the first pressure and the protective gas at the second pressure.

The control module 180 may also control the operation of the heating module 160 based on a temperature of the chamber 110 or 120 acquired through the temperature gauge 175. The processing gas may reach a process temperature based on the operation of the heating module 160.

The control module 180 may also control the gas exhaust module 140 or the gas intake module 150 to bring the processing area 115 to the normal-pressure state or the vacuum state. In detail, when controlling the gas intake module 150, the control module 180 may operate the first vacuum pump 155a first and then the second vacuum pump 155b.

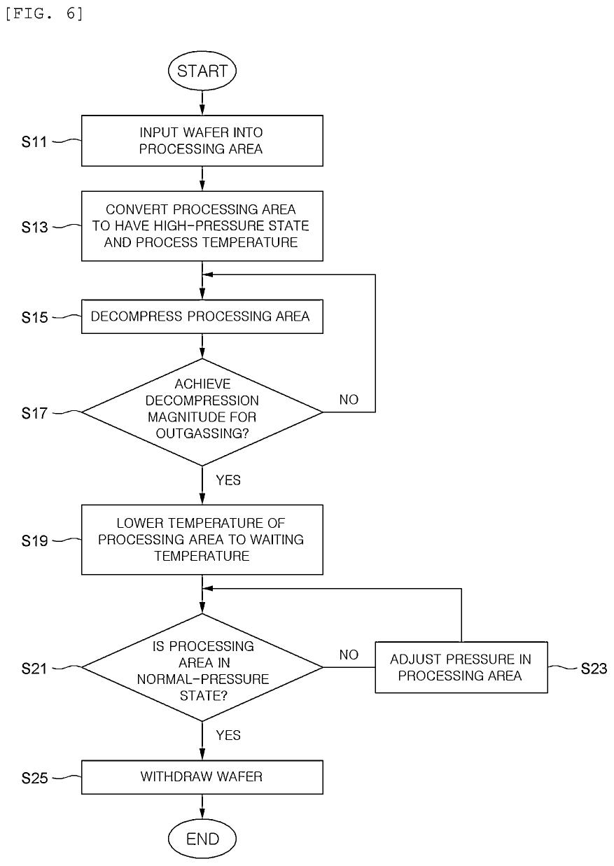

Next, the description describes a wafer processing method using a wafer processing apparatus 100 for a combined high-pressure process and vacuum process with reference to FIGS. 5 to 7.

FIG. 5 is a flowchart for explaining the wafer processing method using decompression according to another embodiment of the present invention.

Referring to this drawing (and FIGS. 1 to 4), the control module 180 may control the gas supply module 130, the gas exhaust module 140, and the gas intake module 150 for the wafer processing to be performed under pressure changes. The pressure change may be, for example, decompression (or pressure reduction). The decompression may be achieved from the high pressure through the normal pressure to vacuum. A decompression magnitude may be 2 ATM or more.

For this processing, the wafer input into the processing area 115 may be exposed to the high-pressure state (S1). The control module 180 may control the gas supply module 130 to input the processing gas into the processing area 115. The processing area 115 may be brought to the high-pressure state by the processing gas. The processing gas may be nitrogen or argon gas, which is the inert gas.

The wafer may be exposed to the decompression from the high pressure to the normal pressure (S3). For this purpose, the control module 180 may control the gas exhaust module 140 to exhaust the processing gas from the processing area 115.

The wafer may be further exposed to the decompression from the normal pressure to the vacuum (S5). For this purpose, the control module 180 may control the gas intake module 150 to suction the residual gas in the processing gas from the processing area 115.

Through this configuration, the wafer may undergo large decompression from the high pressure to the vacuum. The decompression (and subsequent rapid discharge 4 the processing gas) may result in outgassing of the impurity gas from the wafer.

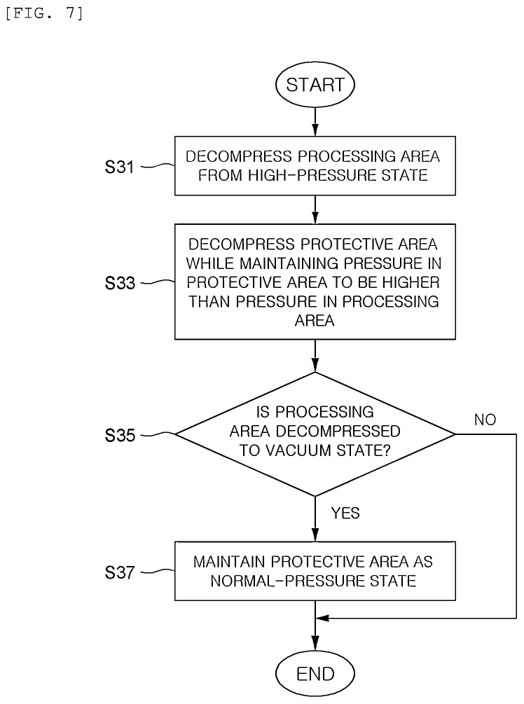

Details of the outgassing are described with further reference to FIG. 6. FIG. 6 is a flowchart for explaining a wafer processing method using decompression according to still another embodiment of the present invention.

Referring further to this drawing, the wafer may be input into the processing area 115 when the processing area 115 has the normal pressure and a waiting temperature (S11). The waiting temperature may be determined within a range of 200° C. to 300° C.

After the wafer input, the processing area 115 may be converted to the high-pressure state. In addition, the temperature of the processing area 115 may also be increased to the process temperature (S13). The process temperature may have a value set within a range of 300° C. to 800° C. The control module 180 may control the heating module 160 to satisfy the process temperature.

The control module 180 may decompress the processing area 115 (S15). The control module 180 may control the gas exhaust module 140 to lower the pressure in the processing area 115 within a range of the high pressure, or convert the processing area 115 to the normal-pressure state from the high-pressure state. The control module 180 may also convert the processing area 115 to the vacuum state from the high-pressure state through the normal-pressure state. In this case, the control module 180 may need to sequentially operate not only the gas exhaust module 140 but also the gas intake module 150.

The control module 180 may determine whether a decompression magnitude has a level for achieving the outgassing (S17). In detail, the control module 180 may determine whether the decompression magnitude is 2 ATM or more. The wafer may undergo the outgassing when the decompression magnitude in the processing area 115 is 2 ATM or more. During the outgassing process, the process temperature may be maintained at the same set value. In this case, the outgassing may be performed more smoothly.

After the outgassing, the control module 180 may lower the temperature of the processing area 115 from the process temperature to the waiting temperature (S19). For this purpose, the control module 180 may naturally cool the processing area 115 or operate a cooling module (not shown) to forcibly cool the processing area 115.

The control module 180 may determine whether the pressure in the processing area 115 based on the decompression is the normal pressure (S21). The control module 180 may determine a current pressure in the processing area 115 based on a measured value of the pressure gauge 171.

The control module 180 may adjust the pressure in the processing area 115 to the normal pressure when the processing area 115 is not in the normal-pressure state (S23). The control module 180 may supply the processing gas to the processing area 115 through the gas supply module 130 when the processing area 115 is in the vacuum state. On the contrary, the control module 180 may exhaust the processing gas from the processing area 115 through the gas exhaust module 140 when the processing area 115 is in the high-pressure state.

The wafer may be withdrawn from the processing area 115 when the processing area 115 is in the normal-pressure state (S25). The control module 180 may open the doors of the internal chamber 110 and the external chamber 120 to allow the wafer to come out of the processing area 115.

The description describes a method of controlling the pressure in the internal chamber 110 or the external chamber 120 during the wafer processing with further reference to FIG. 7. FIG. 7 is a flowchart for explaining a wafer processing method using decompression according to yet another embodiment of the present invention.

Referring further to this drawing, in order to reach the high-pressure state, the protective area 125 may also be pressed when pressing the processing area 115. In a pressing process, the pressure in the protective area 125 may be higher than the pressure in the processing area 115. The processing area 115 may be decompressed from the high pressure (S31).

The protective area 125 may also be decompressed in keeping with the decompression of the processing area 115 (S33). Even in a process of decompressing the protective area 125, the pressure in the protective area 125 may be maintained to be higher than the pressure in the processing area 115.

The control module 180 may determine whether the processing area 115 is finally decompressed to the vacuum for the wafer processing (S35).

Even when the processing area 115 is decompressed to the vacuum, the protective area 125 may be decompressed only to the normal pressure or higher (S37). A difference between the pressure in the processing area 115 and the pressure in the protective area 125 may be maintained at a level of 1 ATM, and accordingly, there is no need to convert the protective area 125 to the vacuum state. In this case, the suction pipe 151 of the gas intake module 150 may need to communicate only to the processing area 115, and may not need to communicate with the protective area 125 (see FIG. 1).

When it is determined that the processing area 115 is finally decompressed to the normal pressure (S35), the protective area 125 may be decompressed to a pressure higher than that in the processing area 115 based on the control in a prior step S33.

The wafer processing apparatus for a combined high-pressure process and vacuum process, and the wafer processing method using decompression, as described above are not limited to the configurations and operation methods of the embodiments described above. The embodiments described above may be variously modified by selective combinations of all or some of the respective embodiments.

### Industrial Applicability

The present invention has potential industrial application in fields of manufacturing the wafer processing apparatus for a combined high-pressure process and vacuum process, and wafer processing using decompression.

1. A wafer processing method using decompression, the method comprising:
supplying a processing gas to a processing area for the processing area to be in a high-pressure state that is higher than that of atmospheric pressure, thereby exposing a wafer disposed in the processing area to the high-pressure state;
exhausting the processing gas from the processing area for the processing area to be converted to a normal-pressure state, thereby exposing the wafer to decompression from a high pressure to a normal pressure; and
suctioning residual gas in the processing gas from the processing area for the processing area to be converted to the vacuum state, thereby exposing the wafer to decompression from the normal pressure to vacuum.

2. The method of claim 1, wherein in the high-pressure state, a pressure in the processing area reaches a set value within a range of 2 ATM to 25 ATM.

3. The method of claim 1, wherein in the vacuum state, a pressure in the processing area reaches a set value within a range of 10\hat{ }−3 Torr to 10\hat{ }−7 Torr.

4. The method of claim 1, wherein when a pressure is converted from the high-pressure state to the vacuum state, a decompression magnitude is 2 ATM or more.

5. The method of claim 1, further comprising maintaining a pressure in a protective area accommodating the processing area to be higher than a pressure in the processing area while converting the processing area to the vacuum state from the high-pressure state.

6. The method of claim 1, wherein in the suctioning of the residual gas in the processing gas from the processing area for the processing area to be converted to the vacuum state, thereby exposing the wafer to the decompression from the normal pressure to vacuum,
a pressure in a protective area accommodating the processing area is maintained to be in the normal-pressure state or more when converting the processing area to the vacuum state.

7. The method of claim 1, wherein in the exhausting of the processing gas from the processing area for the processing area to be converted to the normal-pressure state, thereby exposing the wafer to the decompression from the high pressure to the normal pressure,
a gas exhaust valve for regulating a gas exhaust pipe connected to the processing area is opened to naturally exhaust the processing gas.

8. The method of claim 1, wherein the suctioning of the residual gas in the processing gas from the processing area for the processing area to be converted to the vacuum state, thereby exposing the wafer to the decompression from the normal pressure to vacuum, includes
operating a first vacuum pump communicating to the processing area, and
operating a second vacuum pump disposed between the processing area and the first vacuum pump, and operated at a lower pressure than the first vacuum pump,
wherein the first vacuum pump is operated by being bypass-connected to a flow path between the processing area and the second vacuum pump when the second vacuum pump is not operated.

9. The method of claim 1, further comprising bringing a temperature of the processing area to a set value within a range of 300° C. to 800° C. while converting the processing area to the vacuum state from the high-pressure state.

10. A wafer processing apparatus for a combined high-pressure process and vacuum process, the apparatus comprising:
a process chamber having a processing area for processing a wafer;
a gas supply module configured to supply a processing gas to the processing area for the processing area to reach a high-pressure state that is higher than that of atmospheric pressure;
gas exhaust module configured to exhaust the processing gas from the processing area for the processing area to reach a normal-pressure state;
a gas intake module configured to suction residual gas in the processing gas from the processing area for the processing area to reach a vacuum state; and
a control module configured to control the gas supply module, the gas exhaust module, and the gas intake module for the wafer processing to be performed under pressure changes from the high-pressure state through the normal-pressure state to the vacuum state.

11. The apparatus of claim 10, wherein the process chamber includes
an internal chamber including the processing area, and
an external chamber accommodating the internal chamber, and
the gas supply module is configured to supply, to the external chamber, a protective gas at a pressure higher than a pressure of the processing gas.

12. The apparatus of claim 10, wherein the gas intake module includes
a suction unit, and
a suction pipe allowing the suction unit and the processing area to communicate with each other, and
the gas exhaust module includes a gas exhaust pipe branching off from the suction pipe and having a smaller diameter than the suction pipe.

13. A wafer processing method using decompression, the method comprising:
decompressing a processing area from a high-pressure state to at least one of the high-pressure state, a normal-pressure state, and a vacuum state among the high-pressure state where a processing gas is supplied to the processing area for the processing area to have a pressure higher than atmospheric pressure, the normal-pressure state where the processing gas is exhausted from the processing area and the processing area reaches a normal pressure, and the vacuum state where residual gas in the processing gas is suctioned from the processing area and the processing area reaches vacuum; and
causing outgassing in a wafer disposed in the processing area by decompressing the processing area,
wherein in the decompressing of the processing area from the high-pressure state to the at least one of the high-pressure state, the normal-pressure state, and the vacuum state among the high-pressure state where the processing gas is supplied to the processing area for the processing area to have the pressure higher than the atmospheric pressure, the normal-pressure state where the processing gas is exhausted from the processing area and the processing area reaches the normal pressure, and the vacuum state where the residual gas in the processing gas is suctioned from the processing area and the processing area reaches the vacuum,
a decompression magnitude is 2 ATM or more.

14. The method of claim 13, further comprising bringing a temperature of the processing area to a set value within a range of 300° C. to 800° C. when pressing and decompressing the wafer.

15. The method of claim 14, wherein in the bringing of the temperature of the processing area to the set value within the range of 300° C. to 800° C. when pressing and decompressing the wafer,
a temperature of the processing area is maintained at the same temperature while decompressing the wafer.
